(19) United States
(12) Patent Application Publication
(10) Pub. No.: US 2006/0255459 A1
(43) Pub. Date: Nov. 16, 2006

(54) Stacked semiconductor memory device

(76) Inventors: Simon Muff, Hohenkirchen (DE); Srdjan Djordjevic, Munchen (DE); Holger Schroeter, Munchen (DE); Siva RaghuRam, Germering (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/126,408

(22) Filed: May 11, 2005

(51) Int. Cl. H01L 23/48

(52) U.S. Cl. 257/738

(57) ABSTRACT

A stacked semiconductor memory device includes memory device contacts to externally connect the stacked semiconductor memory device to a printed circuit board. In a dual or quad stack configuration, the stacked semiconductor memory device includes a first package which is stacked above a second package. The first and second packages are preferably designed as FBGA packages, each of them including package contacts. By providing first and second flexible circuit structures to connect the package contacts of the first and second packages to the memory device contacts, a symmetrical stacked package configuration is obtained. This configuration facilitates transmission of signals with improved signal integrity via a bus of the printed circuit board between the stacked semiconductor memory device and a controller chip, even if the frequency of the bus or the load of the stacked semiconductor memory is increased.

### FIELD OF THE INVENTION

The invention relates to a stacked semiconductor memory device, especially to a dual or quad stacked semiconductor memory device. The invention also relates to a semiconductor memory module comprising stacked semiconductor memory devices.

### BACKGROUND

FIG. 1 shows a semiconductor memory module 1000 which is designed, for example, as a buffered DIMM (dual in-line memory module). The memory module includes semiconductor memory devices 100 and a controller device 200. The controller device 200 and the semiconductor memory devices are arranged at a top and a bottom surface of a printed circuit board 300. The controller device 200 is fixed to the printed circuit board 300 by controller device contacts 201. In the same way, the semiconductor memory devices are fixed to the printed circuit board 300 by memory device contacts 101. The controller device contacts 201 and the memory device contacts 101 are formed, for example, as leads, bumps or solder balls.

In a buffered DIMM, the integrated semiconductor memory devices are shielded from the external environment by means of the controller device 200. The controller device 200 communicates with a memory controller and controls read and write accesses to the semiconductor memory devices 100 in response to memory controller commands. Control signals generated by the controller device 200, which is, for example, designed as a HUB chip, are transmitted via a bus structure 400 which is located inside the printed circuit board 300 to each of the semiconductor devices 100. For reasons of simplicity, FIG. 1 only shows one bus line 400. In a practical embodiment several bus lines, such as DQ(data queue)-bus lines, CA(command address)-bus lines, CTRL(control)-bus lines and CLK(clock)-bus lines, are provided inside the printed circuit board for transmitting data, control, address and clock signals between the controller device 200 and the semiconductor memory devices 100.

In order to increase the density of a semiconductor memory module, the semiconductor memory devices 100 do not only comprise one single integrated semiconductor memory chip inside their casings, but usually include two or more semiconductor memory chips.

FIG. 2 shows a stacked package configuration which is arranged inside one of the casings of the integrated semiconductor memory devices 100 to increase the density of the buffered DIMM. A package 110 is stacked above a package 120. Each of the packages 110/120 has a top surface T110/T120 and a bottom surface B110/B120. An integrated semiconductor memory chip 112/122 is usually stuck on a ground plane inside the package 110/120. In a dual stack design, only one integrated semiconductor memory chip is arranged in each of the packages 110 or 120. In a quad stack design, two integrated semiconductor memory chips are arranged in each of the packages 110 or 120. Each of the integrated semiconductor memory chips is connected by substrate to wire-bonds 114/124 to contact pads 113/123.

FIG. 3 shows a simplified schematic drawing of a memory cell array SZF which is included in each of the integrated semiconductor memory chips 112 and 122. Memory cells SZ are arranged in the memory cell array, constructed from rows and columns in a matrix form, between wordlines WL and bitlines BL. A single DRAM (dynamic random access memory) cell SZ comprises a storage capacitor SC which can be connected to one of the bitlines BL by means of a selection transistor AT. A control connection of the selection transistor is connected to one of the wordlines. For a read or write access to the DRAM memory cell, the selection transistor is turned on by actuating it using an appropriate control signal on the wordline, so that the storage capacitor is connected to the bitline via a conductive path of the selection transistor. Depending on the charge state of the storage capacitor, which corresponds to a logic information item stored in the memory cell, the bitline experiences a rise in potential or a fall in potential in comparison with a precharge potential to which the bitlines in the memory cell array have been charged generally prior to the read or write access. A sense amplifier connected to the bitline amplifies the generally small rise or fall in potential of the bitline to produce a high or low voltage potential. In case of a read access the high voltage potential which represents a logic high level of a data signal or the low voltage potential which represents a logic low level of a data signal is transferred via bus structure 400 from the stacked semiconductor memory device 100 to the controller device 200 which communicates with the external environment of the DIMM.

The contact pads 113 of the package 110 are located at the bottom surface B110 of the package 110. Each of the contact pads of the package 110 is connected to a package contact 111 of the package 110. In the same way, the contact pads 123 of the package 120 are located at the bottom surface B120 of package 120. Each of the contact pads of the package 120 is connected to a package contact 121 of the package 120. An underfill material 160 is arranged between the package contacts 121 of the package 120 in FIG. 2. For reasons of simplicity the underfill material is only shown between the package contacts 121, but the underfill material is typically also provided between package contacts 111.

The package contacts 111 are connected to the memory device contacts 101 by means of a conductive track 131. The conductive track is preferably arranged on the surface of a flexible circuit structure 130. An area at an end of the flexible circuit structure 130 which is in contact with the package contacts 111 is stuck by means of an adhesive 150 on the top surface T120 of the package 120, whereas an area at the other end of the flexible circuit structure 130 is located between package contacts 121 of the package 120 and the memory device contacts 101 of the integrated semiconductor memory device 100. The flexible circuit structure 130 is bent around the lateral sides of the package 120 and electrically connects the package contacts 111 of the package 110, illustrated in FIG. 2 as solder balls, with the memory device contacts 101 of the semiconductor memory device 100, which are also designed as solder balls in the embodiment of FIG. 2. In contrast to the package contacts 111, the package contacts 121 of the package 120 are just separated from the semiconductor memory device contacts 101 via the flexible circuit structure 130. Therefore, in contrast to the package contacts 111, the package contacts 121 can be considered as “directly” connected to the memory device contacts 101.

FIGS. 4A, 4B, 4C and 4D show eye diagrams of a data signal of a fully buffered DIMM in a quad stacked configuration at a frequency of 200 MHz. FIG. 4A shows the eye diagram of a data signal transmitted on the DQ-bus and generated by a first integrated semiconductor memory chip inside the package 110. FIG. 4B shows the eye diagram of a data signal transmitted on the DQ-bus and generated by a second integrated semiconductor memory chip inside the package 110. The aperture of the eye diagrams which represents a measure of the signal integrity on the DQ-bus has a value of 69% for FIG. 4A and a value of 70% for FIG. 4B.

FIG. 4C shows an eye diagram for a data signal transmitted on the DQ-bus and generated by a first integrated semiconductor memory chip located inside the package 120. FIG. 4D shows an eye diagram of a data signal transmitted on the DQ-bus and generated by a second integrated semiconductor memory chip located inside package 120. Each of the eye diagrams of FIGS. 4C and 4D has an aperture of 52%. This low aperture value indicates a bad signal integrity on the DQ-bus, especially for data signals which are generated by one of the integrated semiconductor memory chips inside the bottom package 120.

Signal integrity for data signals decreases, if the frequency (by which signals such as data, address or command signals are driven on the bus structure 400) increases. A further influence on the signal integrity represents the load of the integrated semiconductor memory devices which are connected to the bus structure 400. If the load, which depends on the number of chips integrated in a package, is increased, the signal integrity on the bus structure gets worse. The load of each integrated semiconductor memory device is increased when a stacked DRAM configuration is used. In a dual stack (4R×8) DIMM configuration, the load of four individual integrated semiconductor memory chips has to be driven per bus line. In a quad stack (8R×8) DIMM configuration, the load of eight individual integrated semiconductor memory chips has to be driven per bus line.

As shown in FIG. 2, current package technology is using only one flexible circuit structure to connect the upper package 110 including upper chip/die 112 (dual stack) or upper dual chip/die (quad stack) to the memory device contacts 101. A load imbalance results in that the bottom package 120 is “directly” soldered on the balls 101 and that the upper package 110 is connected to the balls 101 via a long stub length of the bended flexible circuit structure 130. Due to this asymmetry in the embodiment of the packages inside the casing of the stacked semiconductor memory device, there is a tendency, especially for data, address and control signals generated by the integrated semiconductor memory chip inside the bottom package 120, to eye collapse on the bus between the controller device and the stacked semiconductor memory device due to reflections.

U.S. Pat. No. 6,576,992 describes two CSPs (chip scale package integrated circuits) which are stacked, with one CSP disposed, in a two-high CSP stack or module. The two CSPs are connected with a pair of flex circuits. Each of the pair of flex circuits is partially wrapped about a respective opposite lateral edge of the lower CSP of the module. The flex circuit pair connects the upper and lower CSPs and provides a thermal and electrical connection path between the module and an application environment such as a printed wiring board (PWB).

### SUMMARY

An object of the present invention is to provide a stacked semiconductor memory device that transmits signals on a bus connected to the stacked semiconductor memory device with superior signal integrity.

Another object of the present invention is to provide a semiconductor memory module that transmits signals on a bus connected to the stacked semiconductor memory device with a great signal integrity.

The aforesaid and other objects are achieved individually and/or in combination, and it is not intended that the present invention be construed as requiring two or more of the objects to be combined unless expressly required by the claims attached hereto.

In accordance with the present invention, a stacked semiconductor memory device comprises a memory device contact to externally connect the stacked semiconductor memory device, a first package including a top surface and a bottom surface and comprising at least one first package contact arranged or disposed at the bottom surface, and a second package including a top surface and a bottom surface and comprising at least one second package contact arranged or disposed at the bottom surface of the second package. In addition, the stacked semiconductor memory device comprises a first conductive track and a second conductive track. The first package is stacked above the second package. The first package contact is connected by the first conductive track to the memory device contact and the second package contact is connected by the second conductive track to the memory device contact.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 depicts an embodiment of a semiconductor memory module.

FIG. 2 depicts a stacked semiconductor memory device of the prior art.

FIG. 3 depicts an embodiment of a memory cell array.

FIGS. 4A to 4D are eye diagrams of data signals on a bus connected to a stacked semiconductor memory device designed according to the prior art.

FIG. 5 depicts an embodiment of a stacked semiconductor memory device according to the present invention.

FIGS. 6A and 6B depict an embodiment of a layered structure of a first and second flexible circuit structure according to the present invention.

FIGS. 7A to 7D are eye diagrams of data signals on a bus connected to a stacked semiconductor memory device with a resistance of 50 Ohm for each of the conductive tracks according to the present invention.

FIGS. 8A to 8D are eye diagrams of data signals on a bus connected to a stacked semiconductor memory device with a resistance of 90 Ohm for each of the conductive tracks according to the present invention.

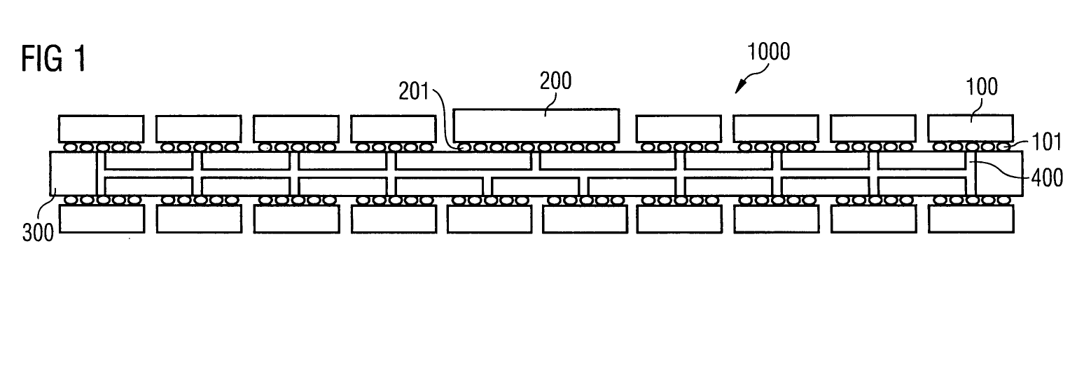

### DETAILED DESCRIPTION

In accordance with the present invention, a stacked semiconductor memory device comprises a memory device contact to externally connect the stacked semiconductor memory device, a first package including a top surface and a bottom surface and comprising at least one first package contact arranged at the bottom surface, and a second package including a top surface and a bottom surface and comprising at least one second package contact arranged at the bottom surface of the second package. In addition, the stacked semiconductor memory device comprises a first conductive track and a second conductive track. The first package is stacked above the second package. The first package contact is connected by the first conductive track to the memory device contact and the second package contact is connected by the second conductive track to the memory device contact.

Although the memory device contacts are located right under or directly below the second package contacts, the second package contacts are not soldered directly to the memory device contacts. According to the present invention, the electric connection between the second package contact and the memory device contact is achieved by providing a second conductive track, which serves as a “dummy” conductive track. By using a first conductive track to connect the first package contacts to the memory device contacts and by using a second conductive track to connect the second package contacts to the memory device contacts, a symmetrical stacked package configuration is obtained. The symmetrical stacked package configuration enables a high signal integrity to be achieved on the bus connected between a controller device and the stacked semiconductor memory device, such as the DQ-bus, the CA-bus, the CTRL- or the CLK-bus. The symmetrical stacked package configuration facilitates the transmission of data, address, control and clock signals on the bus between the stacked semiconductor memory device and the controller device, even if the frequency on the bus is increased or if the load of the stacked semiconductor memory device is increased by using a dual or quad stack configuration.

In an embodiment of the stacked semiconductor memory device, each of the first and second conductive tracks is formed as a flexible conductive track.

In order to obtain a symmetrical stacked semiconductor memory device, it is preferred that each of the first and second conductive tracks is designed with the same length and the same resistance.

In another embodiment of the stacked semiconductor memory device, each of the first and second conductive tracks has a resistance of 50 Ohm or greater. Preferably, each of the first and second conductive tracks has a resistance of 90 Ohm.

The stacked semiconductor memory device can further include a first and second flexible circuit structure. The first conductive track is formed as a conductive layer of the first flexible circuit structure. The second conductive track is formed as a conductive layer of the second flexible circuit structure.

According to another embodiment of the stacked semiconductor memory device, each of the first and second flexible circuit structures includes a non-conductive layer, a first contact pad and a second contact pad. The conductive layer of the first flexible circuit structure is arranged at the non-conductive layer of the first flexible circuit structure. The first contact pad of the first flexible circuit structure is arranged at an area of the conductive layer of the first flexible circuit structure. The second contact pad of the first flexible circuit structure is arranged at an area of the conductive layer of the first flexible circuit structure. The conductive layer of the second flexible circuit structure is arranged at the non-conductive layer of the second flexible circuit structure. The first contact pad of the second flexible circuit structure is arranged at an area of the conductive layer of the second flexible circuit structure. The second contact pad of the second flexible circuit structure is arranged at an area of the conductive layer of the second flexible circuit structure.

According to a further embodiment of the stacked semiconductor memory device, the first contact pad of the first flexible circuit structure is connected to the first package contact. The second contact pad of the first flexible circuit structure is connected to the memory device contact. The first contact pad of the second flexible circuit structure is connected to the second package contact. The second contact pad of the second flexible circuit structure is connected to the second contact pad of the first flexible circuit structure.

In still another embodiment of the stacked semiconductor memory device, an area of the non-conductive layer of the first flexible circuit structure is arranged or disposed under the area of the conductive layer of the first flexible circuit structure, where the first contact pad of the first flexible circuit structure is located, is stuck by means of an adhesive on the top surface of the second package. The first flexible circuit structure is bent in such a way that the second contact pad of the first flexible circuit structure is connected to the memory device contact. An area of the non-conductive layer of the second flexible circuit structure arranged under the area of the conductive layer of the second flexible circuit structure, where the first contact pad of the second flexible circuit structure is located, is stuck by means of an adhesive on an area of the non-conductive layer of the second flexible circuit structure arranged under the area of the conductive layer of the second flexible circuit structure, where the second contact pad of the second flexible circuit structure is located.

Each of the first and second flexible circuit structures can be formed as a single-sided flexible circuit, a double-sided flexible circuit, a multilayer flexible circuit or a rigid-flex circuit.

In accordance with another embodiment of the stacked semiconductor memory device, each of the conductive layers of the first and second flexible circuit structures is made of copper. In addition, each of the non-conductive layers of the first and second flexible circuit structures is made of polymide.

Each of the first package contact and the second package contact can be designed or configured as a solder ball or as a bump. Preferably, each of the first and second packages is designed or configured as a fine-pitch ball grid array package.

In another embodiment of the stacked semiconductor memory device, each of the first and second packages includes at least one integrated semiconductor memory chip. When the integrated semiconductor memory chip is a DRAM chip, the DRAM chip includes dynamic random access memory cells.

A semiconductor memory module is formed in accordance with the present invention that includes at least one of the previously described stacked semiconductor memory devices.

In a preferred embodiment, the semiconductor memory module includes a controller device, a printed circuit board and at least one bus structure. The stacked semiconductor memory device and the controller device are mounted on the printed circuit board. The controller device is configured such that it controls read and write accesses to the stacked semiconductor memory device by control signals transferred via the bus structure.

According to another preferred embodiment, the semiconductor memory module is designed as a dual in-line memory module.

The invention is now further described with reference to the figures.

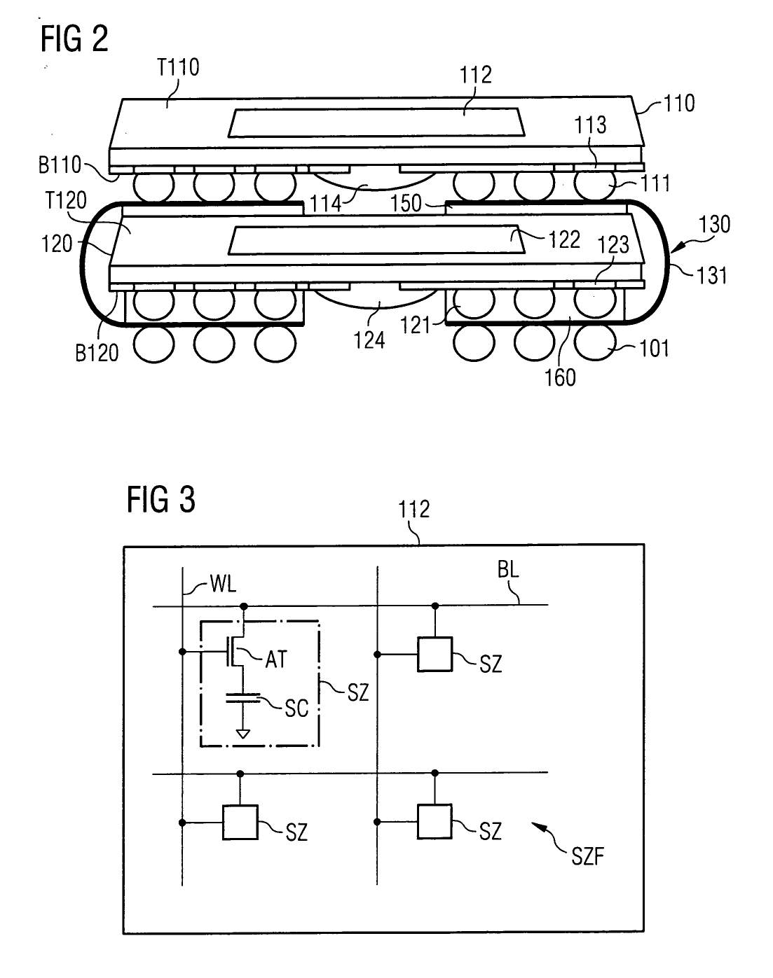

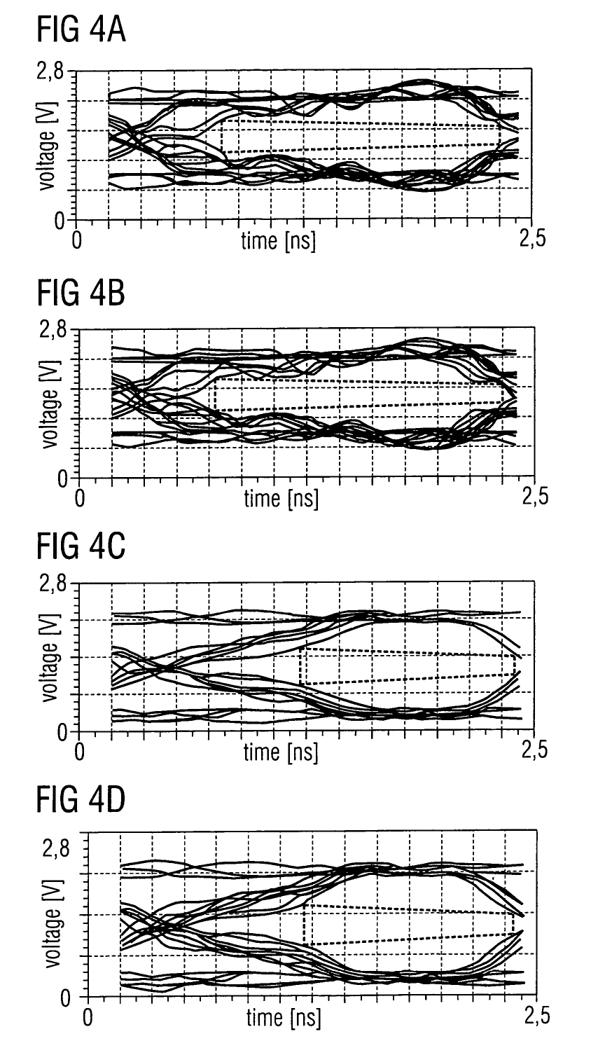

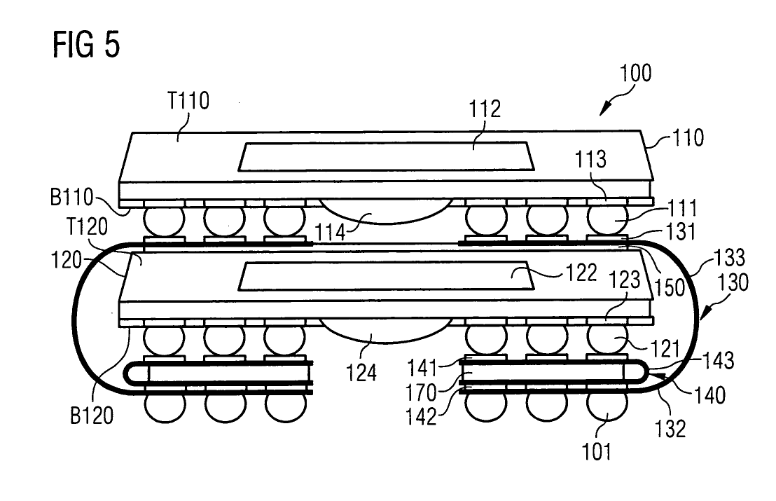

FIG. 5 shows a package configuration of a stacked semiconductor memory device according to the present invention. Identical or substantially similar features of FIGS. 2 and 5 are indicated with the same reference signs. In a dual stack configuration, a package 110 includes an integrated semiconductor memory chip 112. In a quad stack configuration, the package 110 includes two integrated semiconductor memory chips. The integrated semiconductor memory chip 112 preferably includes a memory cell array, such as shown in FIG. 3, with DRAM cells and is connected via substrate to die wire-bonds 114 and to contact pads 113 located at a bottom surface B110 of the package 110. The package 110 is preferably formed as a FBGA (fine-pitch ball grid array) package. It has an array of package contacts 111 being formed as bumps or solder balls.

The package 120 which is stacked under the package 110 is formed of the same structure. It includes one integrated semiconductor memory chip or two integrated semiconductor memory chips in dependence on a dual or quad stack package configuration. The integrated semiconductor memory chip 122 is connected via substrate to die wire-bonds 124 and to contact pads 123 located at a bottom surface B120 of the package 120. The package 120 is preferably formed as an FBGA package. It has an array of package contacts 121 at the bottom surface B120. The package contacts 121 may be designed as bumps or solder balls.

In order to connect the solder balls 111 of the package 110 to the memory device contacts 101, a flexible circuit structure 130 is provided. Contact pads 131 are arranged on an area at a first end of the flexible circuit structure 130. The area under the first end of the flexible circuit structure 130 is stuck by means of an adhesive 150 to the top surface T120 of the package 120. Further contact pads 132 are arranged on an area at a second end of the flexible circuit structure 130. The solder balls 111 of the package 110 are connected via the contact pads 131, via a conductive track 133 disposed on a surface of the flexible circuit structure 130 and via the contact pads 132 to the memory device contacts 101. For this purpose the flexible circuit structure 130 is bent around a lateral side of the lower stacked package 120.

In order to connect the solder balls 121 of the package 120 to the memory device contacts 101, the solder balls 121 are not soldered directly to the balls 101, but via a “dummy” flexible circuit structure 140. Contact pads 141 are arranged on an area at a first end of the flexible circuit structure 140, and contact pads 142 are arranged on an area at a second end of the flexible circuit structure 140. The contact pads 141 and the contact pads 142 are connected via a conductive track 143 disposed on the surface of the flexible circuit structure 140.

The flexible circuit structure 140 is preferably formed with the same characteristic as the flexible circuit structure 130. By way of example, both conductive tracks 133 and 143 of the flexible circuit structures 130 and 140 have the same lengths and the same resistance. The solder balls 121 are connected via the contact pads 141, via the conductive track 143 on the surface of the flexible circuit structure 140 and via the contact pads 142 to the solder balls 101. Flexible circuit structure 140 is bent in the same manner as the flexible circuit structure 130. The area located between the area at the first end and the area at the second end of the flexible circuit structure 140 is filled with an adhesive 170.

FIG. 6A shows in greater detail an area of a layered structure of the flexible circuit structure 130 which is stuck on the top surface of the package 120. A conductive layer 133 is disposed on a non-conductive layer 134. The contact pad 131 is disposed on the conductive layer 133. The conductive layer includes the conductive track which connects the contact pad 131 to the contact pad 132. It consists, for example, of copper. The non-conductive layer 134 consists, for example, of polymide. According to the embodiment shown in FIG. 6A the flexible circuit structure 130 is formed as a single-sided flexible circuit. However, it may also be designed as a double-sided flexible circuit, a multilayer flexible circuit or a rigid flexible circuit.

FIG. 6B shows the layered structure of the flexible circuit structure 130 and the flexible circuit structure 140 in an area under the solder ball contacts 121. The flexible circuit structure 140 is also shown in FIG. 6B as a single-sided flexible circuit, but may also be designed as a double-sided flexible circuit, a multilayer flexible circuit or as a rigid flexible circuit. The contact pad 141 is disposed on top of a conductive layer 143 which, for example, is made of copper. According to the single-sided design, the conductive layer 143 is disposed on a non-conductive layer 144 which is preferably made of polymide. The flexible circuit structure 140 is bent in a small radius such that an area of the non-conductive layer 144, which is located under an area of the conductive layer 143 on which the contact pad 141 is disposed, and an area of the non-conductive layer 144, which is located under an area of the conductive layer 143 on which the contact pad 142 is disposed, are arranged opposite to each other. Due to the small bend radius, the flexible circuit structure 140 has a small U-form. The areas of the non-conductive layer 144 which are located opposite to each other are fixed together by the adhesive 170.

In order to connect the contact pad 142 to one of the solder balls 101, the contact pad 142 is in contact with the conductive layer 133 of the flexible circuit structure 130 and is also electrically connected to the contact pad 132 via the conductive layer 133. In order to connect the contact pad 142 to the conductive layer 133, the non-conductive layer 134 is removed in the area under the contact pad 132, for example by an etch process, such that the contact pad 142 is in contact with the conductive layer 133 through a small window.

By using a “dummy” flexible circuit structure 140 for electrically connecting the package contacts 121 of the lower stacked package 120 to the memory device contacts 101, a symmetrically stacked package configuration is obtained.

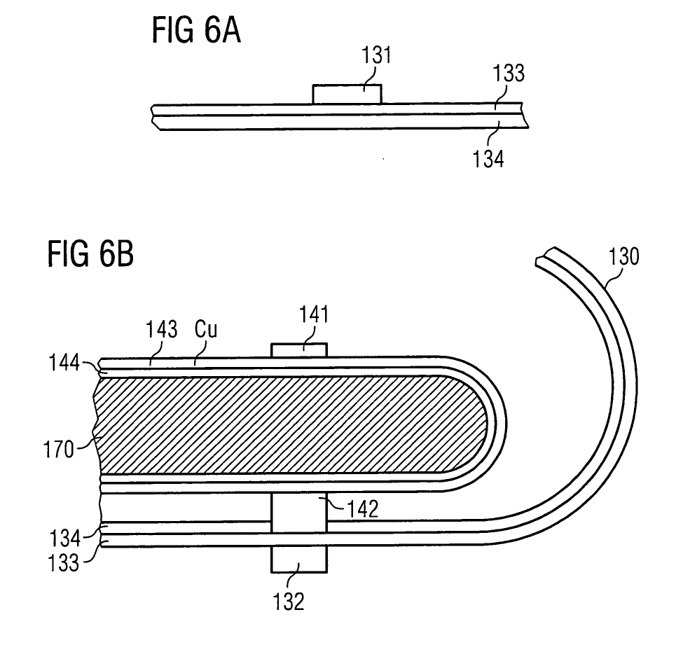

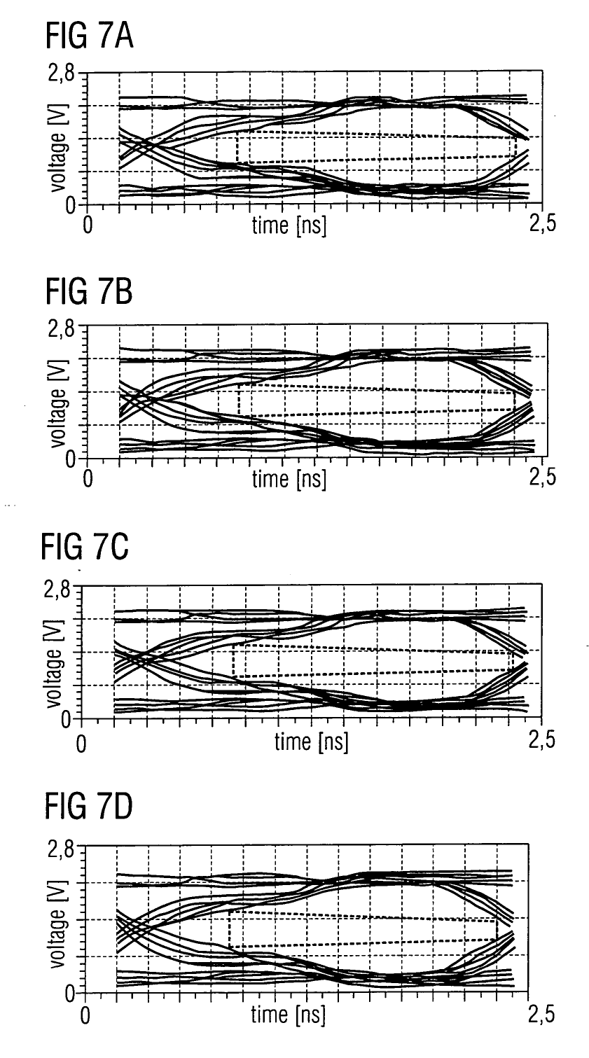

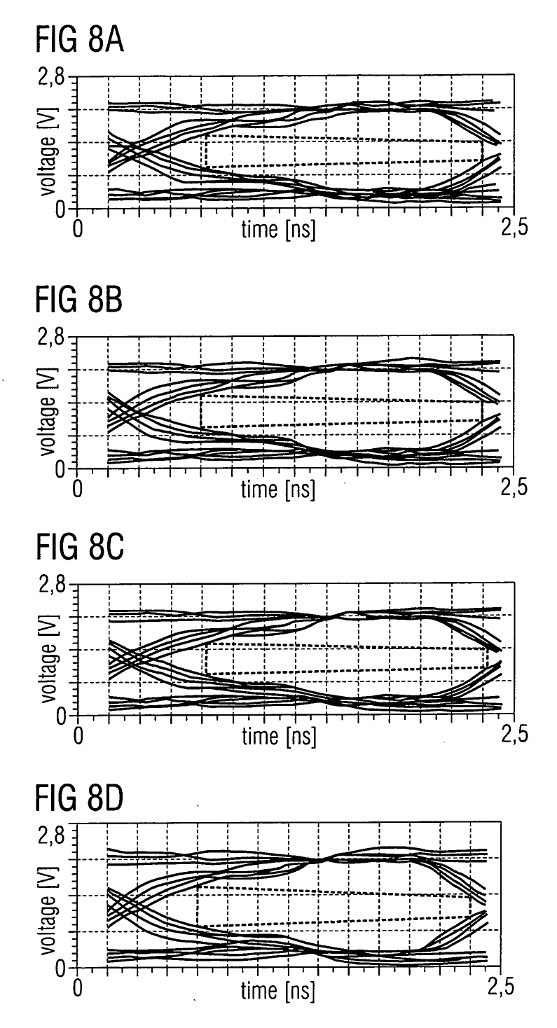

FIGS. 7 and 8 are eye diagrams that show the signal integrity when data signals are transferred via the bus structure between the symmetrical stacked package configuration according to the present invention and the controller device 200.

FIG. 7A is an eye diagram of a data signal on the DQ-bus generated by a first semiconductor memory which is located inside the package 110. FIG. 7B is an eye diagram of a data signal on the DQ-bus generated by a second semiconductor memory which is also located inside the package 110. For both data signals, the eye diagrams show an aperture of about 67%.

FIG. 7C is an eye diagram of a data signal on the DQ-bus generated by a first semiconductor memory which is arranged inside the package 120. FIG. 7D is an eye diagram of a data signal on the DQ-bus generated by a second semiconductor memory which is arranged inside the package 120. For both data signals, the eye diagrams show an aperture of 67%. For the stacked package configuration according to prior art ,as shown in FIG. 2, the aperture of data signals which are generated by one of the integrated semiconductor memories inside the lower package 120 was only about 52%.

The eye diagrams of FIGS. 7A to 7D characterize the signal integrity for a resistance of the conductive tracks of the flexible circuit structures 130 and 140 of 50 Ohm. The eye diagrams of FIGS. 8A to 8D characterize the signal integrity for a resistance of the conductive tracks of the flexible circuit structures 130 and 140 of about 90 Ohms.

FIG. 8A is an eye diagram of a data signal on the DQ-bus generated by a first semiconductor memory, whereas FIG. 8B is an eye diagram of a data signal on the DQ-bus generated by a second semiconductor memory. Both of the first and second semiconductor memories are located inside the package 110. For both data signals, the eye diagrams have an aperture of about 71%.

FIG. 8C is an eye diagram of a data signal on the DQ-bus generated by a first semiconductor memory, whereas FIG. 8D is an eye diagram of data signal on the DQ-bus generated by a second semiconductor memory. Both of the first and second semiconductor memories are located inside the package 120. For both data signals, the eye diagrams have an aperture of about 71%.

The comparison between the different resistances of the conductive tracks 133 and 143 of the flexible circuit structures 130 and 140 shows that the signal integrity is further improved if the resistance of the conductive track 133 of the flexible circuit structure 130 and the resistance of the conductive track 143 of the “dummy” flexible circuit structure 140 is increased from 50 Ohm to 90 Ohm.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

100 stacked semiconductor memory device
101 memory device contact
110 first package
111 package contact of the first package
112 integrated semiconductor memory chip of the first package
113 contact pad of the first package
114 substrate to die wire-bonds
120 second package
121 package contact of the second package
122 integrated semiconductor memory of the second package
123 contact pad of the second package
124 substrate to die wire-bonds of the second package
130 flexible circuit structure
131, 132 contact pads of flexible circuit structure 130
133 conductive layer of the first flexible circuit structure
134 non-conductive layer of the first flexible circuit structure
140 flexible circuit structure
141, 142 contact pads of flexible circuit structure 140
143 conductive layer of the second flexible circuit structure
144 non-conductive layer of the second flexible circuit structure
150, 170 adhesive
160 underfill material
200 controller circuit
201 contact of the controller device
300 printed circuit board
400 bus structure
AT selection transistor
BL bitline
SC storage capacitor
SZ memory cell
SZF memory cell array
WL wordline

What is claimed is:

1. A stacked semiconductor memory device, comprising:
a memory device contact to externally connect the stacked semiconductor memory device to a structure;
a first package including a top surface and a bottom surface, the first package comprising at least one first package contact disposed at the bottom surface of the first package;
a second package including a top surface and a bottom surface, the second package comprising at least one second package contact disposed at the bottom surface of the second package;
a first conductive track; and
a second conductive track;
wherein:
the first package is stacked above the second package;
the first package contact is connected by the first conductive track to the memory device contact; and
the second package contact is connected by the second conductive track to the memory device contact.

2. The stacked semiconductor memory device of claim 1, wherein each of the first and second conductive tracks is formed as a flexible conductive track.

3. The stacked semiconductor memory device of claim 1, wherein the first and second conductive tracks have the same lengths and the same resistances.

4. The stacked semiconductor memory device of claim 1, wherein each of the first and second conductive tracks has a resistance of 50 Ohm.

5. The stacked semiconductor memory device of claim 1, wherein each of the first and second conductive tracks has a resistance of 90 Ohm.

6. The stacked semiconductor memory device of claim 1, further comprising:
a first flexible circuit structure; and
a second flexible circuit structure;
wherein the first conductive track is formed as a conductive layer of the first flexible circuit structure and the second conductive track is formed as a conductive layer of the second flexible circuit structure.

7. The stacked semiconductor memory device of claim 6, wherein:
each of the first and second flexible circuit structures comprises a non-conductive layer, a first contact pad and a second contact pad;
the conductive layer of the first flexible circuit structure is disposed at the non-conductive layer of the first flexible circuit structure;
the first contact pad of the first flexible circuit structure is disposed at an area of the conductive layer of the first flexible circuit structure;
the second contact pad of the first flexible circuit structure is disposed at an area of the conductive layer of the first flexible circuit structure;
the conductive layer of the second flexible circuit structure is disposed at the non-conductive layer of the second flexible circuit structure;
the first contact pad of the second flexible circuit structure is disposed at an area of the conductive layer of the second flexible circuit structure; and
the second contact pad of the second flexible circuit structure is disposed at an area 20 of the conductive layer of the second flexible circuit structure.

8. The stacked semiconductor memory device of claim 7, wherein:
the first contact pad of the first flexible circuit structure is connected to the first package contact;
the second contact pad of the first flexible circuit structure is connected to the memory device contact;
the first contact pad of the second flexible circuit structure is connected to the second package contact; and
the second contact pad of the second flexible circuit structure is connected to the second contact pad of the first flexible circuit structure.

9. The stacked semiconductor memory device of claim 7, wherein:
the non-conductive layer of the first flexible circuit structure is secured, at an area that is disposed under the area of the conductive layer of the first flexible circuit structure where the first contact pad of the first flexible circuit structure disposed, via an adhesive to the top surface of the second package;
the first flexible circuit structure is bent such that the second contact pad of the first flexible circuit structure is connected to the memory device contact;
the non-conductive layer of the second flexible circuit structure is secured, at an area disposed under the area of the conductive layer of the second flexible circuit structure where the first contact pad of the second flexible circuit structure is secured, via an adhesive, to an area of the non-conductive layer of the second flexible circuit structure that is disposed under the area of the conductive layer of the second flexible circuit structure where the second contact pad of the second flexible circuit structure is disposed.

10. The stacked semiconductor memory device of claim 6, wherein each of the first and second flexible circuit structures is formed as a single-sided flexible circuit.

11. The stacked semiconductor memory device of claim 6, wherein each of the first and second flexible circuit structures is formed as a double-sided flexible circuit.

12. The stacked semiconductor memory device of claim 6, wherein each of the first and second flexible circuit structures is formed as a multilayer flexible circuit.

13. The stacked semiconductor memory device of claim 6, wherein each of the first and second flexible circuit structures is formed as a rigid-flex circuit.

14. The stacked semiconductor memory device of claim 6, wherein each of the conductive layers of the first and second flexible circuit structure comprises copper.

15. The Stacked semiconductor memory device of claim 6, wherein each of the non-conductive layers of the first and second flexible circuit structure comprises polymide.

16. The stacked semiconductor memory device of claim 1, wherein each of the first package contact and the second package contact is configured as a solder ball or as a bump.

17. The stacked semiconductor memory device of claim 1, wherein each of the first and second packages is configured as a fine-pitch ball grid array package.

18. The stacked semiconductor memory device of claim 1, wherein each of the first and second packages includes at least one integrated semiconductor memory chip.

19. The stacked semiconductor memory device of claim 1, wherein the integrated semiconductor memory chip comprises dynamic random access memory cells.

20. A semiconductor memory module, comprising:
at least one stacked semiconductor memory device as recited in claim 1,
a controller device;
a printed circuit board; and
at least one bus structure;
wherein:
the stacked semiconductor memory device and the controller device are mounted on the printed circuit board; and
the controller device is configured to control read and write accesses to the stacked semiconductor memory device by control signals transferred via the bus structure.

21. The semiconductor memory module of claim 20, wherein the semiconductor memory module is configured as a dual in-line memory module.
